(19) United States
(12) Patent Application Publication
(10) Pub. No.: US 2023/0075263 A1
(43) Pub. Date: Mar. 9, 2023

(54) WAFER BONDING METHOD USING SELECTIVE DEPOSITION AND SURFACE TREATMENT

(71) Applicant: Tokyo Electron Limited, Tokyo (JP)

(72) Inventors: Soo Doo Chae, Albany, NY (US); Sang Cheol Han, Albany, NY (US); Hojin Kim, Albany, NY (US); Kandabara Tapily, Albany, NY (US); Satohiko Hoshino, Albany, NY (US); Adam Gildea, Albany, NY (US); Gerrit Leusink, Albany, NY (US)

(73) Assignee: Tokyo Electron Limited, Tokyo (JP)

(21) Appl. No.: 17/863,594

(22) Filed: Jul. 13, 2022

Related U.S. Application Data
(60) Provisional application No. 63/242,182, filed on Sep. 9, 2021.

(51) Int. Cl. H01L 23/00

(52) U.S. Cl. CPC H01L 24/80; H01L 24/08; H01L 24/05; H01L 2224/05647; H01L 2224/05624; H01L 2224/05684; H01L 2224/05666; H01L 2224/05681; H01L 2224/05686; H01L 2924/04941; H01L 2924/04953; H01L 2224/80379; H01L 2924/05042; H01L 2924/05442; H01L 2924/059; H01L 2924/05432; H01L 2924/0534; H01L 2224/80009; H01L 2224/03452; H01L 2224/03616; H01L 2224/80896; H01L 2224/80201; H01L 2224/80075; H01L 24/03; H01L 2224/08145

(57) ABSTRACT

A semiconductor package is disclosed. The semiconductor package includes a first substrate including a first interconnect structure and a first bonding layer adjacent the first interconnect structure. The semiconductor package includes a second substrate including a second interconnect structure and a second bonding layer adjacent the second interconnect structure. The first bonding layer and second bonding layer each include a metal oxide.

### CROSS-REFERENCE TO RELATED APPLICATIONS

The present application claims the benefit of and priority to U.S. Provisional Patent Application No. 63/242,182, filed Sep. 9, 2021, and entitled “Wafer Bonding Method Using Selective Deposition and Surface Treatment,” the contents of which is incorporated by reference in its entirety for all purposes.

### FIELD OF THE DISCLOSURE

This disclosure relates to microelectronic devices including semiconductor devices, transistors, and integrated circuits, including methods of microfabrication.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed, and greater bandwidth, as well as lower power consumption and latency has grown recently, there has grown a need for smaller and more creative packaging techniques of semiconductor dies.

### SUMMARY

Wafer-to-wafer and chip-to-chip bonding is being implemented to continue Power-Performance-Area-Cost (PPAC) scaling for complex circuits such as are implemented in Systems on Chip (SOCs). Many bonding techniques utilize oxide-to-oxide bonding adhesion and forming integrated interconnect structures through a hybrid bonding technique that enables interconnections to be formed at the bond interface between two wafers or dies. However, prior to bonding the wafers, current technologies typically recess the interconnect structures (e.g., formed with conductive materials, lines, vias, wires, pads, etc.) of respective wafers using at least one etching technique (e.g., wet or dry etching), for instance, to allow proper alignments and expansions (e.g., during a heating or annealing procedures) of the interconnect structures for interconnections. Stated another way, the etching or recessing process of the interconnect structures can cause corner rounding, void, or roughness of the interconnect structures.

The present disclosure provides various embodiments for selective deposition of materials (e.g., oxide materials, sometimes referred to as bonding materials) for interconnection between the two wafers (or dies). For example, each wafer can include a respective substrate (e.g., a first substrate of a first wafer and a second substrate of a second wafer). The first and second substrates can include respective interconnect structures (e.g., composed of conductive materials) and dielectric layers around the sidewall and bottom of the interconnect structures. A selective deposition technique can be performed to deposit oxide materials over the top surface of the dielectric layers. After depositing the oxide materials, the two wafers (e.g., with one of the wafers flipped) can be aligned and bonded/connected/coupled via the oxide materials using at least one bonding/coupling technique. By coupling the wafers, a channel can be formed extending from the top surfaces of the respective interconnect structures. Accordingly, the first and second substrates can be heated/annealed, thereby expanding and physically connecting the interconnect structures of the two wafers. In this way, the present disclosure avoids or minimizes the corner rounding, void, and/or roughness of the interconnect structures when forming the recesses to couple the wafers.

One embodiment may include a semiconductor package. The semiconductor package includes a first substrate. The first substrate includes a first interconnect structure. The first substrate includes a first bonding layer portion adjacent the first interconnect structure. The semiconductor package includes a second substrate coupled to the first substrate. The second substrate includes a second interconnect structure. The second substrate includes a second bonding layer portion adjacent the second interconnect structure. At least one of the first bonding layer portion and the second bonding layer portion include a metal oxide.

A top surface of the first interconnect structure is in contact with a top surface of the second interconnect structure, and a top surface of the first bonding layer portion is in contact with a top surface of the second bonding layer portion. The first substrate further includes a first dielectric material embedding a lower portion of the first interconnect structure, and the second substrate further includes a second dielectric material embedding a lower portion of the second interconnect structure.

The first bonding layer portion and the second bonding layer portion contact each other along a bond interface. The first substrate further includes a plurality of first device features disposed opposite the first interconnect structure from the second interconnect structure. The second substrate further includes a plurality of second device features disposed opposite the second interconnect structure from the first interconnect structure.

The first bonding layer portion is disposed around an upper portion of the first interconnect structure, and the second bonding layer portion is disposed around an upper portion of the second interconnect structure. The metal oxide is selected from the group consisting of: aluminum oxide (Al₂O₃), hafnium oxide (HfO₂), and combinations thereof

Another embodiment may include a method for fabricating semiconductor packages. The method includes providing a first substrate including a first dielectric layer and a first interconnect structure. The method includes selectively forming a first bonding layer only on the first dielectric layer. The method includes providing a second substrate including a second dielectric layer and a second interconnect structure. The method includes coupling the first substrate to the second substrate based on physically contacting the first interconnect structure and the first bonding layer with the second interconnect structure and the second dielectric layer, respectively.

The step of coupling the first substrate to the second substrate further comprises selectively forming a second bonding layer only on the second dielectric layer. The method includes coupling the first substrate to the second substrate based on physically contacting the first interconnect structure and the first bonding layer with the second interconnect structure and the second bonding layer, respectively. The first bonding layer and the second bonding layer each include a material selected from the group consisting of: silicon oxide (SiO₂), silicon nitride (SiN), silicon carbonitride (SiCN), silicon oxycarbonitride (SiOCN), aluminum oxide (Al₂O₃), hafnium oxide (HfO₂), and combinations thereof. The method includes rinsing the first substrate with DI water to hydrophilize the first bonding layer.

The step of coupling the first substrate to the second substrate further comprises aligning the first interconnect structure with the second interconnect structure. The method includes physically contacting the first bonding layer with the second dielectric layer. The method includes annealing the first substrate and the second substrate to physically contact the first interconnect structure with the second interconnect structure.

The step of selectively forming a first bonding layer comprise performing at least one atomic layer deposition process. Prior to selectively forming the first bonding layer, the method includes performing a first polishing process on the first substrate to form a first coplanar surface shared by the first dielectric layer and the first interconnect structure.

Following selectively forming the first bonding layer, a top surface of the first interconnect structure is recessed from a top surface of the first bonding layer.

Yet another embodiment may include a method for fabricating semiconductor packages. The method includes providing a first substrate including a first dielectric layer and a first interconnect structure exposed at a surface of the first dielectric layer. The method includes forming a first bonding layer on the first dielectric layer using an atomic deposition process. The method includes providing a second substrate including a second dielectric layer and a second interconnect structure. The method includes bonding the first bonding layer with the second substrate. The method includes physically contacting the first interconnect structure with the second interconnect structure.

The first bonding layer include a material selected from the group consisting of: silicon oxide (SiO₂), silicon nitride (SiN), silicon carbonitride (SiCN), silicon oxycarbonitride (SiOCN), aluminum oxide (Al₂O₃), hafnium oxide (HfO₂), and combinations thereof. Prior to physically contacting the first bonding layer with second bonding layer, the method includes rinsing the first substrate with DI water to hydrophilize the first bonding layer.

The first dielectric layer is formed to a thickness of 1-10 nm thereby forming a recess between a surface of the first bonding layer and a surface of the first interconnect structure, and wherein after bonding the first bonding layer with the second substrate an anneal is performed to physical contact the first interconnect structure with the second interconnect structure through the recess. Following forming the first bonding layer, a top surface of the first interconnect structure is recessed from a top surface of the first bonding layer.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of an example method for making a semiconductor package, in accordance with some embodiments.

FIGS. 2A to 6B illustrate respective cross-sectional views of a semiconductor package during various fabrication stages, made by the method of FIG. 1, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

According to one implementation, a process for fabricating a semiconductor package is provided utilizing selective deposition and wafer bonding technique(s). By utilizing the selective deposition technique, a recessed region can be formed above the top surface of the interconnect structures for the wafers before coupling or physically connecting the two wafers (or dies). For example, each wafer can include a respective substrate (e.g., a first substrate of a first wafer and a second substrate of a second wafer). The first and second substrates can include respective interconnect structures (e.g., composed of conductive materials) and dielectric layers around the sidewall and bottom of the interconnect structures. A selective deposition technique can be performed to deposit oxide materials over the top surface of the dielectric layers. After depositing the oxide materials, the two wafers (e.g., with one of the wafers flipped) can be aligned and bonded/connected/coupled via the oxide materials using at least one bonding/coupling technique. By coupling the wafers, a channel can be formed extending from the top surfaces of the respective interconnect structures. Therefore, the first and second substrates can be heated/annealed, thereby expanding and physically connecting the interconnect structures of the two wafers. Accordingly, the present disclosure avoids or minimizes the corner rounding, void, and/or roughness of the interconnect structures when forming the recesses to couple the wafers and further enhances efficiency (e.g., time reduction) in bonding the wafers.

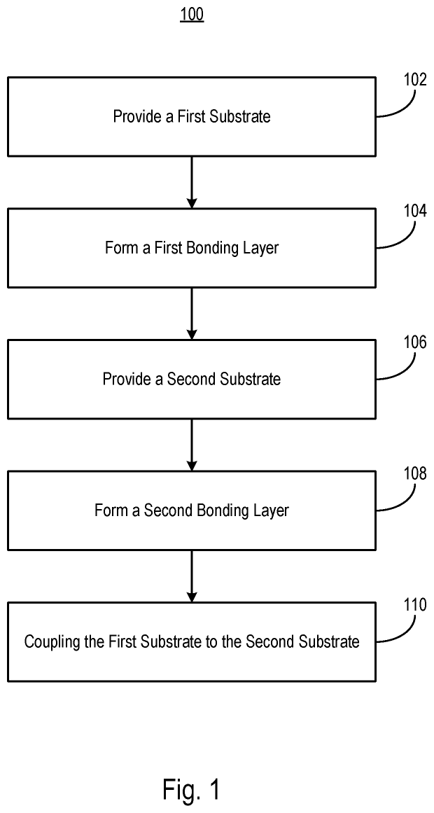

FIG. 1 illustrates a flowchart of an example method 100 for using selective deposition and surface treatment on the surface of a wafer, die, or other substrate to bond (e.g., couple) the surface (e.g., of the wafer) to the surface of another wafer, die, or other substrate. It is noted that the method 100 is merely an example and is not intended to limit the present disclosure. Accordingly, it is understood that additional operations may be provided before, during, and after the method 100 of FIG. 1, and that some other operations may only be briefly described herein.

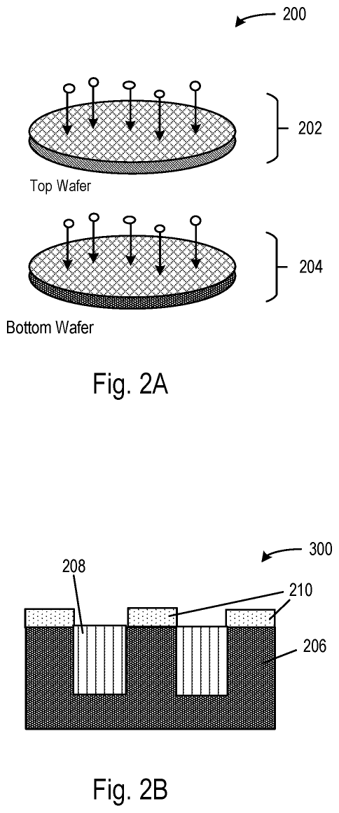

In various embodiments, operations of the method 100 may be associated with perspective views and cross-sectional views of an example semiconductor package 200 at various fabrication stages as shown in FIGS. 2A to 6B, respectively, which will be discussed in further detail below. It should be understood that the semiconductor package 200, shown in FIGS. 2A to 6B, may include a number of other devices such as inductors, fuses, capacitors, coils, etc., while remaining within the scope of the present disclosure. In overview, the method 100 can include providing a first substrate 102. The method can include forming a first bonding layer 104 (e.g., sometimes referred to as a first bonding layer portion). The method can include providing a second substrate 106. The method can include forming a second bonding layer 108 (e.g., sometimes referred to as a second bonding layer portion). The method can include coupling the first substrate to the second substrate 110.

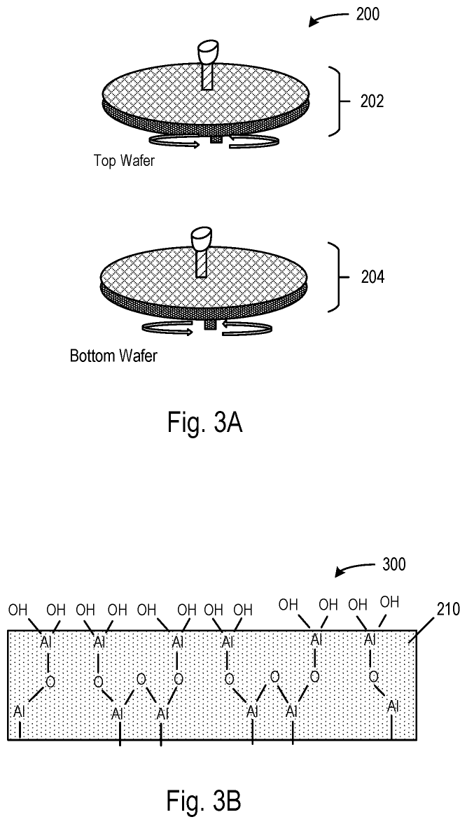

Corresponding to operation 102-108 of FIG. 1, FIG. 2A illustrates a perspective view of the semiconductor package 200 and FIG. 2B illustrates a cross-sectional view 300 of the semiconductor package 200. At least FIGS. 3A-B may also correspond to operation 102-108 of FIG. 1. The semiconductor package 200 can include a first wafer (e.g., top/bottom wafer or die, sometimes referred to as a first substrate) and a second wafer (e.g., bottom/top wafer or die, sometimes referred to as a second substrate). For simplicity and examples, the first wafer can correspond to the top wafer and the second wafer can correspond to the bottom wafer herein. The cross-sectional view 300 can correspond to a cross-sectional view of the first wafer 202 and/or the second wafer 204. In some cases, one or more materials formed for the first wafer 202 may be different from the second wafer 204. In some other cases, the one or more materials formed for the first wafer 202 may be the same as the second wafer 204. For example, the wafers 202, 204 can include or correspond to a respective substrate (not shown). The substrate of the wafers 202, 204 can be a supporting structure forming below or around one or more other materials of the wafers 202, 204.

The substrate may be a semiconductor substrate, such as a bulk semiconductor, a semiconductor-on-insulator (SOI) substrate, or the like, which may be doped (e.g., with a p-type or an n-type dopant) or undoped. The substrate may be or correspond to a respective wafer (e.g., 202 or 204), such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof. The material for each of the two wafers may be different.

In some embodiments, the substrate includes a number of device features (e.g., transistors, diodes, resistors, etc., which are not shown for the sake of clarity) formed along a (e.g., frontside) surface of the substrate and a number of interconnect structures (e.g., metal lines, metal vias, etc., which are not shown for the sake of clarity) formed over the device features. The interconnect structures are configured to electrically connect the device features to one another so as to form an integrated circuit, which can function as a logic device, a memory device, an input/output device, or the like. These interconnect structures (e.g., formed of conductive materials, such as Cu, Al, W, Ti, TiN, Ta, TaN, or multiple layers or combinations thereof) may be embedded in one or more dielectric layers (e.g., formed of low-k dielectric materials, such as SiO₂), which are sometimes referred to as metallization layers, e.g., 206. Alternatively stated, each dielectric layer 206 can include a number of metal lines and a number of metal vias embedded therein. Over the (e.g., frontside) surface of the substrate, one or more of such dielectric layers 206 can be formed. In some cases, the dielectric layer 206 may be formed on the backside of the substrate. The dielectric layer 206, among other materials discussed herein, can be formed or deposited using at least one suitable deposition technique.

As shown, the dielectric layer 206 can be around or surround the sidewall and bottom of the interconnect structure(s) 208. The dielectric layer 206 may =exposes the top surface of the interconnect structure 208. The dielectric layer 206 can extend at least from the bottom of the interconnect structure 208 and along the sidewall of the interconnect structure 208. The top surface of the interconnect structure 208 can be flushed/even/slightly recessed with a plane of the top surface of the dielectric layer 206.

Subsequent to forming the dielectric layer 206 and the interconnect structure 208 of the wafers 202, 204, a bonding layer 210 can be (e.g., selectively) formed or deposited using at least one suitable deposition technique (e.g., selective deposition technique). The bonding layer 210 may sometimes be referred to as a bonding film, material, or structure. The bonding layer 210 can be formed with one or more materials selected from a group including, for example, silicon oxide (SiO₂), silicon nitride (SiN), silicon oxynitride (SiON), silicon carbonitride (SiCN), silicon oxycarbonitride (SiOCN), aluminum oxide (Al₂O₃), hafnium oxide (HfO₂), or combinations thereof, among other types of metal oxide materials. For example, the bonding layer 210 can be (e.g., selectively) formed or deposited by performing at least one suitable deposition process, such as an atomic layer deposition process (ALD, e.g., to deposit materials at exact places), among other types of deposition techniques. Such selective ALD may be referred to as atomic selective deposition (ASD). The bonding layer 210 can be preferentially (or selectively) formed or deposited on the dielectric layer 206 (e.g., on the top surface of the dielectric layer 206). The bonding layer 210 may not be significantly formed on the interconnect structure 208 due to the preferential nature of the ASD process. Such an ASD process may be implemented on either or both of the wafers.

Following the (e.g., selective) formation of the bonding layer 210 the top surface of the interconnect structure 208 can be recessed from the top surface of the bonding layer 210, as shown in at least FIG. 2B. The bonding layer 210 can protrude from the top surface of the dielectric layer 206 by a predetermined height configured for the fabrication/formation/manufacturing process of the semiconductor package 200, such as 1-10 nm, among others. In this case, a dimension (e.g., steepness) of the recess for the top surface of the interconnect structure 208 (e.g., from the top surface of the bonding layer 210) can correspond to the height of the bonding layer 210. At this stage, the interconnect structure 208 can share a coplanar surface with the dielectric layer 206 below the bonding layer 210. In some implementations, the bonding layer 210 can form a channel above the interconnect structure 208 (e.g., the channel corresponding to the recessed portion).

In some implementations, prior to selectively forming the bonding layer for the wafers 202, 204, a portion of at least one of the dielectric layer 206 or the interconnect structure 208 can be polished using at least one suitable polishing process or technique. For example, the surface(s) of the dielectric layer 206 may include excess portions or materials to be removed, such as the top surface of the dielectric layer 206. Hence, a chemical mechanical polishing (CMP) process, an etch process, or combinations thereof can be performed on the surface (e.g., top surface) of the dielectric layer 206 to remove the excess material. In another example, the (e.g., top) surface of the interconnect structure 208 may include excess materials or protrude beyond the top surface of the dielectric layer 206. Accordingly, the interconnect structure 208 may be polished or etched using at least one suitable CMP process, an etching process, or a combination thereof

In various implementations, polishing the top surface of the dielectric layer 206 and the top surface of the interconnect structure 208 can form a shared coplanar surface, where the top surface of the dielectric layer 206 is leveled with the top surface of the interconnect structure 208. For example, prior to forming the bonding layer, polishing the top surface of the first wafer 202 (e.g., the first substrate) can form a first coplanar surface shared by the dielectric layer 206 and the interconnect structure 208 of the first wafer 202. Similarly, polishing the top surface of the second wafer 204 (e.g., the second substrate) can form a second coplanar surface shared by the dielectric layer 206 and the interconnect structure 208 of the second wafer 204.

In some implementations, the surface of one or more materials (e.g., dielectric layer 206, interconnect structure 208, or bonding layer 210) can be treated using at least one suitable surface treatment process or technique, such as a plasma activation procedure. For example, the (e.g., top or exposed) surface of the dielectric layer 206 may be treated to prepare for bonding or coupling with the bonding layer 210 (e.g., treating the material forming the bonding layer 210). In another example, the (e.g., top) surface of the bonding layer 210 may be treated to prepare for bonding with a different bonding layer (e.g., to bond the bonding layer of the first wafer 202 to the bonding layer of the second wafer 204). In some cases, the at least one surface treatment process may not be performed on the one or more materials (e.g., dielectric layer 206, interconnect structure 208, or bonding layer 210). In some other cases, the interconnect structure 208 may be protected (e.g., using a mask, among other materials/covers) during the surface treatment process of at least one of the dielectric layer 206 or the bonding layer 210.

FIG. 3A illustrates a perspective view of the semiconductor package 200 including the first wafer 202 and the second wafer 204. FIG. 3B illustrates a cross-sectional view 300 of the bonding layer 210 of the wafers 202, 204. After (e.g., selectively) depositing the bonding layer 210, a surface hydrophilization process or technique (e.g., among other suitable rinsing techniques) can be performed on the one or more bonding layers 210. For example, the bonding layer 210 can be rinsed by applying deionized (DI) water on the (e.g., top) surface of the bonding layer 210. As shown in at least FIG. 3B, hydroxide (OH) can be introduced to the top surface of the bonding layer 210 via the DI water rinsing process. Therefore, the substrate (e.g., the first or second substrates of the wafers 202, 204) can be rinsed with DI water to hydrophilize the bonding layer 210 of the respective wafers 202, 204. By introducing hydroxide to the surface of the bonding layer 210, the bonding or coupling capabilities between the bonding layer 210 of two wafers 202, 204 can be enhanced (e.g., for preparing the bonding layer 210 for interconnection).

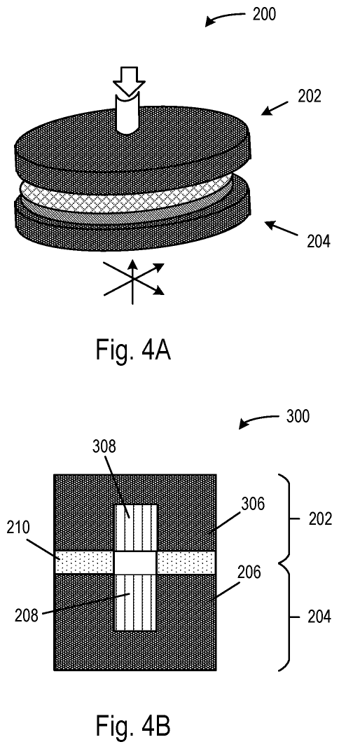

Corresponding to operation 110 of FIG. 1, FIG. 4A illustrates a perspective view of the semiconductor package 200 including the first wafer 202 and the second wafer 204, and FIG. 4B illustrates a cross-sectional view 300 of the wafers 202, 204. As shown, the first wafer 202 can be flipped or inverted (e.g., rotated 180 degrees), where the top of the first substrate (e.g., first wafer 202) is facing down or towards the top of the second substrate (e.g., second wafer 204) facing upward. In some cases, the second wafer 204 can be flipped instead of the first wafer 202. For simplicity and examples herein, the first wafer 202 can include the first substrate including at least the dielectric layer 306 and interconnect structure 308, and the second wafer 204 can include the second substrate including at least the dielectric layer 206 and interconnect structure 208. Either or both of the wafers 202, 204 can include respective bonding layers 210 (e.g., bonded herein to form a connected bonding layer or a single bonding layer, herein simply referred to as bonding layer 210).

After hydrophilizing the bonding layer 210, the wafers 202, 204 (e.g., one flipped) can be aligned and bonded/coupled (e.g., using a hybrid bonding process). For example, the first interconnect structure 308 can be aligned with the second interconnect structure 208. In this case, the bonding layer 210 of the wafers 202, 204 can also be aligned. Aligning the interconnect structures 208, 308 can include or refer to positioning the wafers such that the interconnect structures 208, 308 are directly facing each other. In some cases, the sidewalls of the interconnect structures 208, 308 can be coplanar (e.g., vertical plane).

When the wafers 202, 204 are aligned, the first bonding layer (e.g., bonding layer 210 of the first wafer 202) can physically contact, couple, or interconnect with the second bonding layer (e.g., bonding layer 210 of the second wafer 204). For example, the surface of the bonding layers 210 can be prepared for bonding via at least one of the surface hydrophilization or other surface treatment processes. By applying heat and/or pressure (e.g., during physical contact between the first and second bonding layers of the respective wafers 202, 204), the first and second bonding layers can be coupled/bonded/interconnected. The pressure applied may comprise a pressure of less than about 30 MPa, and the heat applied may comprise an anneal process at a temperature of about 100 to 500 degrees C., as examples, although alternatively, other amounts of pressure and heat may be used for the hybrid bonding process. The hybrid bonding process may be performed in a N₂ environment, an Ar environment, a He environment, an (about 4 to 10% H₂)/(about 90 to 96% inert gas or N₂) environment, an inert-mixing gas environment, combinations thereof, or other types of environments. Hence, the first and second wafers 202, 204 (e.g., first and second substrates) can be coupled based on the physically contacting at least the bonding layers. In some cases, the coupled first and second bonding layers can form the bonding layer 210.

In some implementations, the bond between the wafers 202 (e.g., via the bonding layer 210 at this stage) can include non-metal-to-non-metal bonds or metal-to-metal bonds. A portion of the hybrid bonding process may comprise a fusion process that forms the non-metal-to-non-metal bonds, and a portion of the hybrid bonding process may comprise a copper-to-copper bonding process that forms the metal-to-metal bond, for example. The term “hybrid” refers to the formation of the two different types of bonds (e.g., between the bonding layers 210 and interconnect structures 208, 308) using at least one bonding process, rather than forming only one type of the bonds, as is the practice in other types of wafer-to-wafer or die-to-die bonding processes, for example.

In various implementations, the channels associated with the respective recessed region of the interconnect structures 208, 308 can form a shared channel in response to coupling bonding layers 210. This channel can extend from the top surface of the first interconnect structure 308 to the top surface of the second interconnect structure 208. The channel can provide an opening for the interconnect structures 208, 308 to couple/bond.

In some implementations, the bonding layer 210 may be (e.g., selectively) deposited on the top surface of one of the dielectric layers 206, 306. In this case, the wafers 202, 204 (e.g., one flipped) can be aligned and bonded/coupled using at least one suitable bonding process or technique. For example, the first interconnect structure 308 can be aligned with the second interconnect structure 208. In this case, (e.g., the top surface of) the bonding layer 210 of one of the wafers 202, 204 can also be aligned with (e.g., the top surface of) the dielectric layer 206, 306 of the other wafer 202, 204. The surface of the bonding layer 210 (or the surface of the dielectric layer 206, 306 of the other wafer 202, 204) can be prepared for bonding via at least one suitable surface treatment process, for example. Hence, by applying heat and/or pressure (e.g., during physical contact between the bonding layer 210 and the dielectric layer 206, 306 of the other wafer 202, 204), the two wafers 202, 204 can be coupled/bonded/interconnected.

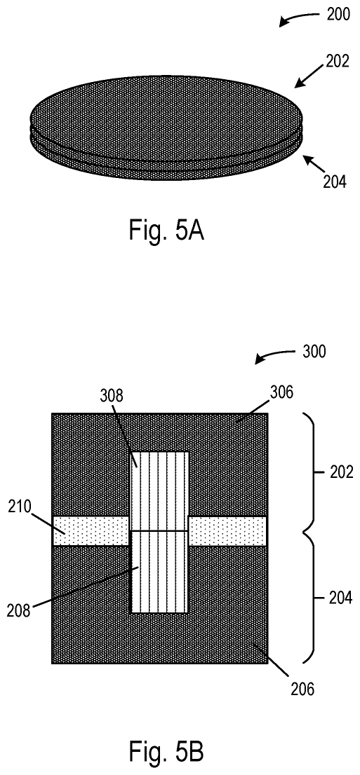

FIG. 5A illustrates a perspective view of the semiconductor package 200 with the coupled first and second wafers 202, 204. FIG. 5B illustrates a cross-sectional view 300 of the coupled wafers 202, 204. For example, after coupling the bonding layers 210, the first substrate and the second substrate can be heated (e.g., annealed or other heating processes) using at least one suitable heat treatment process, such as rapid thermal processing (RTP). Heating the substrates can expand the interconnect structures 208, 308 along the channel surrounded by the bonding layer 210. Hence, annealing the substrates can increase a dimension (e.g., height) of the interconnect structures 208, 308 along the channel to physically contact each other (e.g., create physical contact between the interconnect structures 208, 308 through/via the recessed portion).

In some implementations, the interconnect structures 208, 308 may expand to the same dimension. In some other cases, the interconnect structures 208, 308 may expand in include the same dimension or at the same rate, such that the first or the second interconnect structure 208, 308 expands more than the other for forming the physical contact. In some implementations, the coupling of the first and second substrates (e.g., first and second wafers 202, 204) can refer to or correspond to the coupling of the bonding layers 210 and the interconnect structures 208, 308.

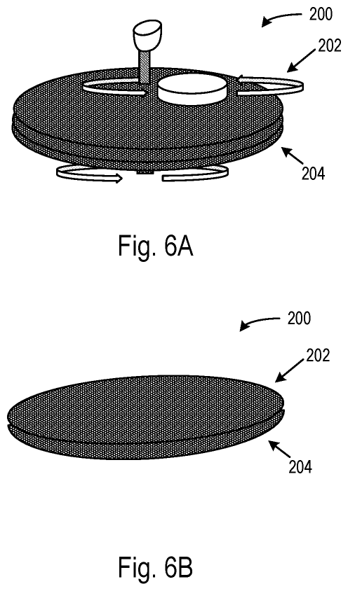

FIG. 6A illustrates a perspective view of the semiconductor package 200 including the first and second wafers 202, 204 undergoing at least one thinning or etching process. FIG. 6B illustrates a perspective view of the semiconductor package 200 including the first and second wafers 202, 204 after the thinning process. The thinning process can be performed before, during, or after bonding the interconnect structures 208, 308. The thinning process can be performed on the first substrate and/or the second substrate using at least one suitable etching technique, such as a chemical etching process.

For example, the bottom surface of the first wafer 202 can be etched or thinned using the at least one suitable etching technique. In some cases, the semiconductor package 200 can be inverted, such that the second wafer 204 (e.g., second substrate) is the top wafer above the first wafer 202 (e.g., first substrate). In this case, the bottom of the second wafer 204 can be etched. In some cases, the semiconductor package 200 may not be inverted, and at least one of the first or second wafers 202, 204 can be etched. Etching the bottom surface of at least one wafer 202, 204 can reduce the dimension (e.g., thickness) of the semiconductor package 200.

In some implementations, after thinning the wafers 202, 204, at least one suitable lithography technique, such as photolithography, can be performed on at least one of the wafers 202, 204. For example, after bonding the various interconnect structures (e.g., 208, 308), thinning the wafers 202, 204, among other fabrication procedures, one or more patterns can be formed in at least one of the first or second substrates, thereby enabling (e.g., electrical) connection with the interconnect structures 208, 308, among other materials.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor package, comprising:
a first substrate including:
a first interconnect structure; and
a first bonding layer portion adjacent the first interconnect structure; and
a second substrate coupled to the first substrate and including:
a second interconnect structure; and
a second bonding layer portion adjacent the second interconnect structure,
wherein at least one of the first bonding layer portion and the second bonding layer portion include a metal oxide.

2. The semiconductor package of claim 1, wherein a top surface of the first interconnect structure is in contact with a top surface of the second interconnect structure, and a top surface of the first bonding layer portion is in contact with a top surface of the second bonding layer portion.

3. The semiconductor package of claim 1, wherein the first substrate further includes a first dielectric material embedding a lower portion of the first interconnect structure, and the second substrate further includes a second dielectric material embedding a lower portion of the second interconnect structure.

4. The semiconductor package of claim 3, wherein the first bonding layer portion and the second bonding layer portion contact each other along a bond interface.

5. The semiconductor package of claim 1, wherein the first substrate further includes a plurality of first device features disposed opposite the first interconnect structure from the second interconnect structure.

6. The semiconductor package of claim 1, wherein the second substrate further includes a plurality of second device features disposed opposite the second interconnect structure from the first interconnect structure.

7. The semiconductor package of claim 1, wherein the first bonding layer portion is disposed around an upper portion of the first interconnect structure, and the second bonding layer portion is disposed around an upper portion of the second interconnect structure.

8. The semiconductor package of claim 1, wherein the metal oxide is selected from a group consisting of: aluminum oxide (Al₂O₃), hafnium oxide (HfO₂), and combinations thereof

9. A method for fabricating semiconductor packages, comprising:
providing a first substrate including a first dielectric layer and a first interconnect structure;
selectively forming a first bonding layer only on the first dielectric layer;
providing a second substrate including a second dielectric layer and a second interconnect structure; and
coupling the first substrate to the second substrate based on physically contacting the first interconnect structure and the first bonding layer with the second interconnect structure and the second dielectric layer, respectively.

10. The method of claim 9, wherein the step of coupling the first substrate to the second substrate further comprises:
selectively forming a second bonding layer only on the second dielectric layer; and
coupling the first substrate to the second substrate based on physically contacting the first interconnect structure and the first bonding layer with the second interconnect structure and the second bonding layer, respectively, and
wherein the first bonding layer and the second bonding layer each include a material selected from a group consisting of: silicon oxide (SiO₂), silicon nitride (SiN), silicon carbonitride (SiCN), silicon oxycarbonitride (SiOCN), aluminum oxide (Al₂O₃), hafnium oxide (HfO₂), and combinations thereof.

11. The method of claim 9, further comprising:
rinsing the first substrate with DI water to hydrophilize the first bonding layer.

12. The method of claim 9, wherein the step of coupling the first substrate to the second substrate further comprises:
aligning the first interconnect structure with the second interconnect structure;
physically contacting the first bonding layer with the second dielectric layer; and
annealing the first substrate and the second substrate to physically contact the first interconnect structure with the second interconnect structure.

13. The method of claim 9, wherein the step of selectively forming the first bonding layer comprises performing at least one atomic layer deposition process.

14. The method of claim 9, further comprising:
prior to selectively forming the first bonding layer, performing a first polishing process on the first substrate to form a first coplanar surface shared by the first dielectric layer and the first interconnect structure.

15. The method of claim 14, wherein following selectively forming the first bonding layer, a top surface of the first interconnect structure is recessed from a top surface of the first bonding layer.

16. A method for fabricating semiconductor packages, comprising:
providing a first substrate including a first dielectric layer and a first interconnect structure exposed at a surface of the first dielectric layer;
forming a first bonding layer on the first dielectric layer using an atomic deposition process;
providing a second substrate including a second dielectric layer and a second interconnect structure;
bonding the first bonding layer with the second substrate; and
physically contacting the first interconnect structure with the second interconnect structure.

17. The method of claim 16, wherein the first bonding layer include a material selected from a group consisting of: silicon oxide (SiO₂), silicon nitride (SiN), silicon carbonitride (SiCN), silicon oxycarbonitride (SiOCN), aluminum oxide (Al₂O₃), hafnium oxide (HfO₂), and combinations thereof.

18. The method of claim 16, prior to physically contacting the first bonding layer with second bonding layer, further comprising:
rinsing the first substrate with DI water to hydrophilize the first bonding layer.

19. The method of claim 16, wherein the first dielectric layer is formed to a thickness of 1-10 nm thereby forming a recess between a surface of the first bonding layer and a surface of the first interconnect structure, and wherein after bonding the first bonding layer with the second substrate an anneal is performed to physical contact the first interconnect structure with the second interconnect structure through the recess.

20. The method of claim 16, wherein following forming the first bonding layer, a top surface of the first interconnect structure is recessed from a top surface of the first bonding layer.
